(19) United States
(12) Patent Application Publication
(10) Pub. No.: US 2022/0123090 A1
(43) Pub. Date: Apr. 21, 2022

(54) FLEXIBLE DISPLAY DEVICE

(71) Applicant: Samsung Display Co., Ltd., Yongin-Si (KR)

(72) Inventors: HEESUNG YANG, Hwaseong-si (KR); SEUNGBAE KANG, Suwon-si (KR)

(21) Appl. No.: 17/352,403

(22) Filed: Jun. 21, 2021

(30) Foreign Application Priority Data
Oct. 19, 2020 (KR) 10-2020-0134892

(51) Int. Cl. H01L 27/32; H01L 51/56

(52) U.S. Cl. CPC H01L 27/3276; H01L 51/0097; H01L 51/56; H01L 27/3258

(57) ABSTRACT

A flexible display device includes an active layer, a source electrode disposed on the active layer, and connected to the active layer by a first contact hole, a drain electrode disposed on a same layer as the source electrode and spaced apart from the source electrode in a first direction, and connected to the active layer by a second contact hole, a first pixel electrode disposed on the drain electrode and including a lower surface electrically connected to the drain electrode while contacting an upper surface of the drain electrode and a via insulating layer disposed between the source electrode and the first pixel electrode, the via insulating layer covering an entirety of the source electrode. The drain electrode penetrates through the via insulating layer and is directly connected to the first pixel electrode.

### PRIORITY STATEMENT

This application claims priority from and the benefit of Korean Patent Application No. 10-2020-0134892, filed on Oct. 19, 2020, which is hereby incorporated by reference for all purposes as if fully set forth herein.

### BACKGROUND

### 1. Field

The present disclosure relates generally to a flexible display device, and more particularly, to a flexible display device with improved luminous efficiency.

### 2. Description of the Related Art

Recently, flexible display devices have been used in various electronic devices such as smart phones, tablets, notebook computers, and home appliances. Accordingly, research is being conducted to increase a luminous efficiency of the flexible display devices.

The flexible display device may include a transistor, an insulating layer disposed on the transistor, and a light emitting diode connected to the transistor. In order to connect the transistor and the light emitting diode, a contact hole connecting the drain electrode of the transistor and the anode electrode of the light emitting diode must be formed. The contact hole may be formed by etching the insulating layer. In this case, the flatness of the upper surface of the insulating layer may be reduced by etching. For this reason, the anode electrode disposed on the insulating layer may not be flatly disposed. Accordingly, the luminous efficiency of the flexible display device decreases.

Therefore, there is need to develop a novel device for disposing the anode electrode flatly.

### SUMMARY

Embodiments provide a flexible display device with improved luminous efficiency.

Additional features of the present disclosure will be set forth in the description which follows, and in part will be apparent from the description, or may be learned by practice of the present disclosure.

In an embodiment of a flexible display device may include an active layer, a source electrode disposed on the active layer, and connected to the active layer by a first contact hole, a drain electrode disposed on a same layer as the source electrode and spaced apart from the source electrode in a first direction, and connected to the active layer by a second contact hole, a first pixel electrode disposed on the drain electrode and including a lower surface electrically connected to the drain electrode while contacting an upper surface of the drain electrode and a via insulating layer disposed between the source electrode and the first pixel electrode, the via insulating layer covering an entirety of the source electrode. The drain electrode may penetrate through the via insulating layer and may be directly connected to the first pixel electrode.

In an embodiment, the source electrode may have a first thickness in a second direction perpendicular to the first direction, the drain electrode may have a second thickness in the second direction, and the second thickness may be thicker than the first thickness.

In an embodiment, the via insulating layer may expose the upper surface of the drain electrode.

In an embodiment, the upper surface of the drain electrode and an upper surface of the via insulating layer may be disposed on a same line.

In an embodiment, a shortest distance between an upper surface of the source electrode and an upper surface of the via insulating layer may be 3000 angstroms.

In an embodiment, the flexible display device may further include a light emitting layer disposed on the first pixel electrode and a second pixel electrode disposed on the light emitting layer.

In an embodiment of a flexible display device may include an active layer, a source electrode disposed on the active layer and connected to the active layer by a first contact hole, a drain electrode disposed on the active layer and connected to the active layer by a second contact hole, a first connection electrode disposed on the source electrode and connected to the source electrode by a third contact hole, a second connection electrode disposed on a same layer as the first connection electrode and connected to the drain electrode by a fourth contact hole, a first pixel electrode disposed on the second connection electrode and including a lower surface while contacting an upper surface of the second connection electrode and a via insulating layer disposed between the first connection electrode and the first pixel electrode, the via insulating layer covering an entirety of the first connection electrode. The second connection electrode may penetrate through the via insulating layer and may be directly connected to the first pixel electrode.

In an embodiment, the first connection electrode may have a first thickness in a second direction perpendicular to the first direction, the second connection electrode may have a second thickness in the second direction, and the second thickness may be thicker than the first thickness.

In an embodiment, a thickness of the source electrode in the second direction may be equal to a thickness of the drain electrode in the second direction.

In an embodiment, the via insulating layer may expose the upper surface of the second connection electrode.

In an embodiment, the upper surface of the second connection electrode and an upper surface of the via insulating layer may be disposed on a same line.

In an embodiment, a shortest distance between an upper surface of the first connection electrode and an upper surface of the via insulating layer may be 3000 angstroms.

In an embodiment, the flexible display device may further include a light emitting layer disposed on the first pixel electrode and a second pixel electrode disposed on the light emitting layer.

In an embodiment of a flexible display device may include an active layer, a source electrode disposed on the active layer and connected to the active layer by a first contact hole, a drain electrode disposed on the active layer and connected to the active layer by a second electrode, a first connection electrode disposed on the source electrode and connected to the source electrode by a third contact hole, a second connection electrode disposed on the drain electrode and connected to the drain electrode by a fourth contact hole, a third connection electrode disposed on the first connection electrode and connected to the first connection electrode by a fifth contact hole, a fourth connection electrode disposed on a same layer as the third connection electrode and connected to the second connection electrode by a sixth contact hole, a first pixel electrode disposed on the fourth connection electrode and including a lower surface while contacting an upper surface of the fourth connection electrode and a via insulating layer disposed between the third connection electrode and the first pixel electrode. the via insulating layer covering an entirety of the third connection electrode. The fourth connection electrode may penetrate through the via insulating layer and may be directly connected to the first pixel electrode.

In an embodiment, the third connection electrode may have a first thickness in a second direction perpendicular to the first direction, the fourth connection electrode may have a second thickness in the second direction, and the second thickness may be thicker than the first thickness.

In an embodiment, a thickness of the source electrode in the second direction and a thickness of the drain electrode in the second direction may be same, and a thickness of the first connection electrode in the second direction and a thickness of the second connection electrode in the second direction may be same.

In an embodiment, the via insulating layer may expose the upper surface of the fourth connection electrode.

In an embodiment, the upper surface of the fourth connection electrode and an upper surface of the via insulating layer may be disposed on a same line.

In an embodiment, a shortest distance between an upper surface of the third connection electrode and an upper surface of the via insulating layer may be 3000 angstroms.

In an embodiment, the flexible display device may further include a light emitting layer disposed on the first pixel electrode and a second pixel electrode disposed on the light emitting layer.

In an embodiment of a flexible display device may include an active layer, a source electrode disposed on the active layer, and connected to the active layer by a first contact hole, a drain electrode disposed on a same layer as the source electrode and spaced apart from the source electrode in a first direction, and connected to the active layer by a second contact hole, a first pixel electrode disposed on the drain electrode and including a lower surface electrically connected to the drain electrode while contacting an upper surface of the drain electrode and a via insulating layer disposed between the source electrode and the first pixel electrode. The drain electrode may penetrate the via insulating layer and is electrically connected to the first pixel electrode.

That is, the first pixel electrode may be connected to the drain electrode without forming a contact hole. Accordingly, it is possible to prevent a decrease in the flatness of the via insulating layer that occurs when the contact hole is formed. Accordingly, the luminous efficiency of the flexible display device may be improved.

### BRIEF DESCRIPTION OF THE DRAWINGS

The above and other features and advantages of the present disclosure will become more apparent by describing in detailed example embodiments thereof with reference to the accompanying drawings.

FIG. 1 is a plan view illustrating a flexible display device according to an embodiment.

FIG. 2 is a cross-sectional view illustrating an embodiment taken along line I-I′ of FIG. 1.

FIG. 3 is a cross-sectional view illustrating an embodiment taken along line I-I′ of FIG. 1.

FIG. 4 is a cross-sectional view illustrating an embodiment taken along line I-I′ of FIG. 1.

FIGS. 5A, 5B, 5C, 5D, and 5E are diagrams illustrating a process of manufacturing the flexible display device of FIG. 1.

### DETAILED DESCRIPTION

Hereinafter, the present disclosure will be explained in detail with reference to the accompanying drawings.

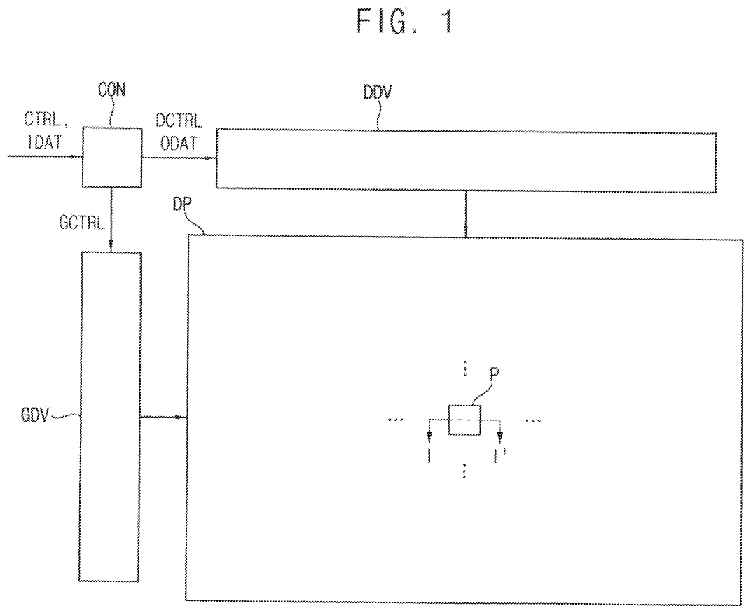

FIG. 1 is a plan view illustrating a flexible display device according to an embodiment. Hereinafter, the flexible display device will be referred to as a display device.

Referring to FIG. 1, the display device may include a display panel DP, a data driver DDV, a gate driver GDV, and a timing controller CON.

In embodiments, the display panel DP may be integrally formed. Alternatively, in embodiments, the display panel DP may include a plurality of sub display panels.

The display panel DP may include a plurality of pixels P. Each of the plurality of pixels P may include light emitting diodes. The display panel DP may display an image through the light emitting diodes. For example, the light emitting diodes may include any one of an organic light emitting diode, a quantum-dot organic light emitting diode, and a quantum-dot nano light emitting diode. Alternatively, the display device may be a liquid crystal display device.

The timing controller CON may generate a gate control signal GCTRL, a data control signal DCTRL, and output image data ODAT based on a control signal CTRL and input image data IDAT provided from an external source. For example, the control signal CTRL may include a vertical synchronization signal, a horizontal synchronization signal, an input data enable signal, a master clock signal, and the like. For example, the input image data IDAT may be RGB data including red image data, green image data, and blue image data. Alternatively, the input image data IDAT may include magenta image data, cyan image data, and yellow image data.

The gate driver GDV may generate gate signals based on the gate control signal GCTRL provided from the timing controller CON. For example, the gate control signal GCTRL may include a vertical start signal, a clock signal, and the like.

The gate driver GDV is electrically connected to the display panel DP and may sequentially output the gate signals. Each of the pixels P may receive a data voltage according to the control of each of the gate signals.

The data driver DDV may generate the data voltage based on the data control signal DCTRL and the output image data ODAT provided from the timing controller CON. For example, the data control signal DCTRL may include an output data enable signal, a horizontal start signal, and a load signal.

The data driver DDV may be electrically connected to the display panel DP and may generate a plurality of data voltages. Each of the pixels P may display an image by receiving a signal for luminance corresponding to each of the data voltages.

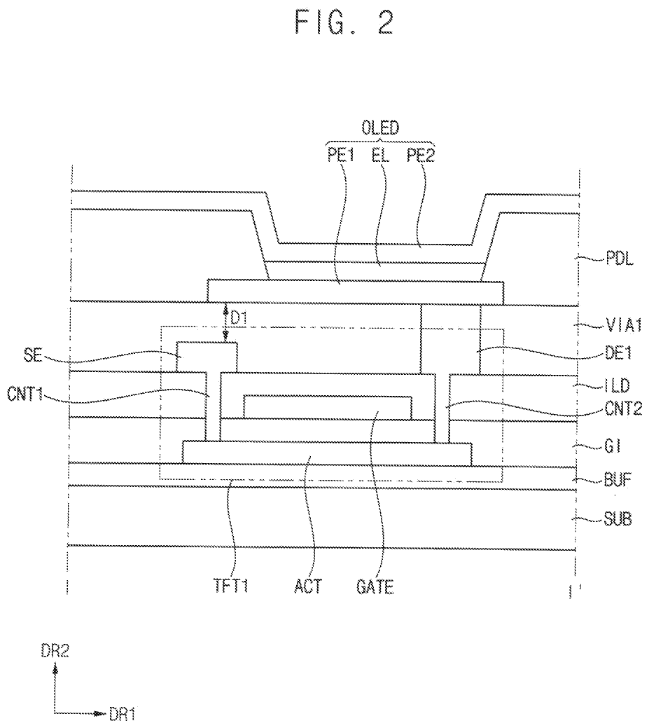

FIG. 2 is a cross-sectional view illustrating an embodiment taken along line I-I′ of FIG. 1.

Referring to FIG. 2, the display device may include a substrate SUB, a buffer layer BUF, a gate insulating layer GI, an interlayer insulating layer ILD, a first via insulating layer VIA1, a pixel defining layer PDL, an organic light emitting diode OLED, and a first transistor TFT1. In embodiments, the organic light emitting diode OLED may include a first pixel electrode PE1, a light emitting layer EL, and a second pixel electrode PE2. In embodiments, the first transistor TFT1 may include an active layer ACT, a gate electrode GATE, a source electrode SE, and a first drain electrode DE1.

The substrate SUB may include polymer or the like. In embodiments, the substrate SUB may include polymer, and accordingly, the display device may have a flexible characteristic. In this case, the substrate SUB may have a structure in which at least one organic film layer and at least one barrier layer are alternately stacked. For example, the organic film layer may be formed using an organic material such as polyimide, and the barrier layer may be formed using an inorganic material.

The buffer layer BUF may be disposed on the substrate SUB. The buffer layer BUF may prevent diffusion of metal atoms or impurities from the substrate SUB into the active layer ACT. In addition, the buffer layer BUF may control a heat supply rate during a crystallization process for forming the active layer ACT, and accordingly, the active layer ACT may be uniformly formed.

The active layer ACT may be disposed on the buffer layer BUF. In embodiments, the active layer ACT may include an oxide-based semiconductor material. For example, the oxide-based semiconductor material may include at least one selected from of zinc oxide (“ZnOx”), tin oxide (“SnOx”), indium oxide (“InOx”), indium-zinc oxide (“IZO”), indium-gallium oxide (“IGO”). zinc-tin oxide (“ZnSnxOy”), and indium-gallium-zinc oxide (“IGZO”).

Alternatively, in embodiments, the active layer ACT may include a silicon-based semiconductor material. For example, the silicon-based semiconductor material may include amorphous silicon, polycrystalline silicon, or the like.

The gate insulating layer GI may be disposed on the buffer layer BUF to cover the active layer ACT. The gate insulating layer GI may include silicon oxide (“SiOx”), silicon nitride (“SiNx”), silicon oxynitride (“SiNxOy”), or the like.

The gate electrode GATE may be disposed on the gate insulating layer GI. The gate electrode GATE may include a conductive material. For example, the gate electrode GATE may include a metal, an alloy, a conductive metal oxide, a transparent conductive material, or the like. For example, the gate electrode GATE may include at least one selected from of silver (“Ag”), an alloy containing silver, molybdenum (“Mo”), an alloy containing molybdenum, aluminum (“Al”), an alloy containing aluminum, and aluminum nitride (“AlN”), tungsten (“W”), tungsten nitride (“WN”), copper (“Cu”), nickel (“Ni”), chromium (“Cr”), chromium nitride (“CrN”), titanium (“Ti”), tantalum (“Ta”), platinum (“Pt”), Scandium (“Sc”), indium tin oxide (“ITO”), indium zinc oxide (“IZO”), and the like.

The interlayer insulating layer ILD may be disposed on the gate insulating layer GI to cover the gate electrode GATE. The interlayer insulating layer ILD may include a silicon compound, a metal oxide, or the like. For example, the interlayer insulating layer ILD may include at least one selected from silicon oxide (“SiOx”), silicon nitride (“SiNx”), silicon oxynitride (“SiNxOy”), or the like.

The source electrode SE and the first drain electrode DE1 may be disposed on the interlayer insulating layer ILD. The source electrode SE and the first drain electrode DE1 may include a metal, an alloy, a conductive metal oxide, a transparent conductive material, and the like. Each of the source electrode SE and the first drain electrode DE1 may be connected to the active layer ACT through a contact hole. The signal transmitted to the source electrode SE may be transmitted to the first drain electrode DE1 through the active layer ACT.

In embodiments, the first drain electrode DE1 may be disposed to be spaced apart from the source electrode SE in the first direction DR1. The source electrode SE may be connected to the active layer ACT through a first contact hole CNT1. The first drain electrode DE1 may be connected to the active layer ACT through a second contact hole CNT2. Each of the first contact hole CNT1 and the second contact hole CNT2 penetrate the interlayer insulating layer ILD and the gate insulating layer GI respectively.

The source electrode SE may have a thickness in a second direction DR2 perpendicular to the first direction DR1. The first drain electrode DE1 may have a thickness in the second direction DR2. In embodiments, the thickness of the first drain electrode DE1 in the second direction DR2 may be thicker than the thickness of the source electrode SE in the second direction DR2.

The first via insulating layer VIA1 may cover the source electrode SE and may be disposed on the interlayer insulating layer ILD. In embodiments, the first via insulating layer VIA1 may be formed of an organic insulating material such as polyimide (“PI”).

The first via insulating layer VIA1 may include an opening exposing the first drain electrode DE1. That is, the first drain electrode DE1 may fill the opening of the first via insulating layer VIA1. The first drain electrode DE1 may penetrate the first via insulating layer VIA1 and contact the first pixel electrode PE1. That is, the first drain electrode DE1 may be connected to the first pixel electrode PE1, and the active layer ACT is connected to the first pixel electrode PE1. A height of the first via insulating layer VIA1 in the second direction DR2 may be substantially the same as a height of the first drain electrode DE1 in the second direction DR2.

In embodiments, the shortest distance D1 between the source electrode SE and the first pixel electrode PE1 may be 3000 angstroms or more. That is, the shortest distance D1 between an upper surface of the first via insulating layer VIA1 and an upper surface of the source electrode SE may be at least 3000 angstroms or more. Thus, it is possible to prevent generation of a parasitic capacitor between the source electrode SE and the first pixel electrode PE1.

The first pixel electrode PE1 may be disposed on the first via insulating layer VIA1. The first pixel electrode PE1 may contact the first drain electrode DE1. Since a height of the first drain electrode DE1 in the second direction DR2 and a height of the first via insulating layer VIA1 in the second direction DR2 may be substantially the same, a lower surface of the first pixel electrode PE1 may directly contact an upper surface of the first drain electrode DE1. The first pixel electrode PE1 may include a metal, an alloy, a conductive metal oxide, a transparent conductive material, or the like. The first pixel electrode PE1 may receive a signal through the first drain electrode DE1. In embodiments, the first pixel electrode PE1 may be an anode electrode.

In this way, if a thickness of the first drain electrode DE1 in the second direction DR2 is formed enough to be thick, then the first drain electrode DE1 and the first pixel electrode PE1 may directly contact each other without a contact hole. That is, it is possible to improve the flatness of the first via insulating layer VIA1 even after the process of forming the contact hole, which may affect the flatness of the first via insulating layer VIA1. As a result, the organic light emitting diode (OLED) is disposed flat, so that the luminous efficiency of the display device may be improved.

The pixel defining layer PDL may cover both ends of the first pixel electrode PE1 along the first direction DR1 and may be disposed on the first via insulating layer VIA1 along the second direction DR2. The pixel defining layer PDL may include an opening exposing at least a portion of the first pixel electrode PE1. The pixel defining layer PDL may serve as a partition wall partitioning a plurality of pixels. In embodiments, the pixel defining layer PDL may include an organic insulating material. For example, the pixel defining layer PDL may include an organic insulating material such as polyimide (“PI”) or hexamethyldisiloxane.

The light emitting layer EL may be disposed on the first pixel electrode PE1. That is, the light emitting layer EL may be disposed in the opening formed by the pixel defining layer PDL. The light emitting layer EL may emit light. To this end, the light emitting layer EL may include a hole injection layer, a hole transport layer, an organic light emitting layer, an electron transport layer, and an electron injection layer.

The second pixel electrode PE2 may be disposed on the light emitting layer EL. The second pixel electrode PE2 may include a metal, an alloy, a conductive metal oxide, a transparent conductive material, or the like. In embodiments, the second pixel electrode PE2 may be a cathode electrode. In embodiments, the second pixel electrode PE2 may be disposed to cover the pixel defining layer PDL and the emission layer EL. The second pixel electrode PE2 may be a common electrode that applies a voltage to the display device.

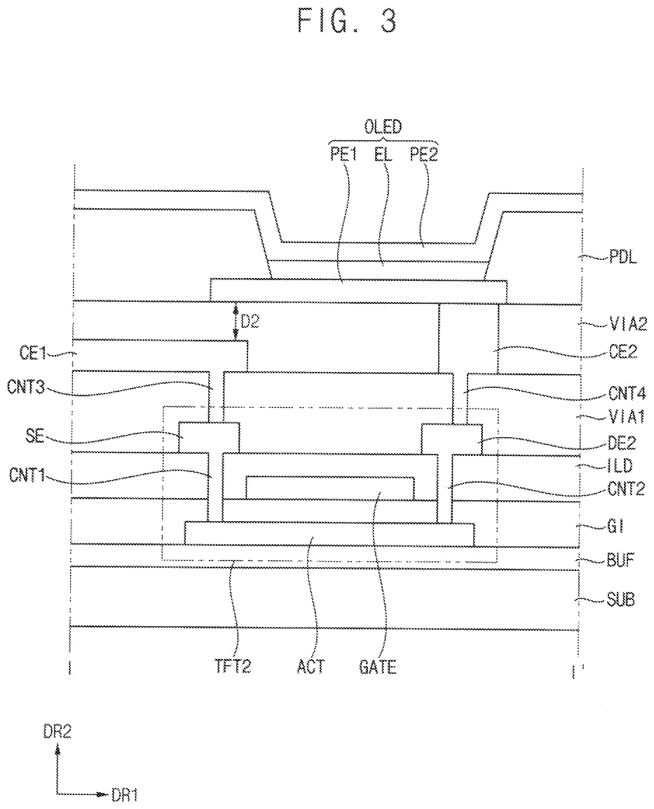

FIG. 3 is a cross-sectional view illustrating an embodiment taken along line I-I′ of FIG. 1. FIG. 3 may be substantially the same as that of FIG. 2 except for a structure between the interlayer insulating layer ILD and the first pixel electrode PE1. Accordingly, the overlapping configuration will be omitted.

Referring to FIG. 3, the display device may include the substrate SUB, the buffer layer BUF, the gate insulating layer GI, the interlayer insulating layer ILD, the first via insulating layer VIA1, a first connection electrode CE1, a second connection electrode CE2, a second via insulating layer VIA2, the pixel defining layer PDL, the organic light emitting diode OLED, and the second transistor TFT2. In embodiments, the second transistor TFT2 may include the active layer ACT, the gate electrode GATE, the source electrode SE, and a second drain electrode DE2.

The source electrode SE and the second drain electrode DE2 may be disposed on the interlayer insulating layer ILD. The second drain electrode DE2 may be disposed to be spaced apart from the source electrode SE in the first direction DR1. The second drain electrode DE2 and the source electrode SE may have substantially the same thickness.

The first via insulating layer VIA1 may be disposed on the interlayer insulating layer ILD to cover the source electrode SE and the second drain electrode DE2. In embodiments, the first via insulating layer VIA1 may be formed of an organic insulating material such as polyimide (“PI”).

The first connection electrode CE1 and the second connection electrode CE2 may be disposed on the first via insulating layer VIA1. The first connection electrode CE1 and the second connection electrode CE2 may include a metal, an alloy, a conductive metal oxide, a transparent conductive material, or the like.

The first connection electrode CE1 may be connected to the source electrode SE through a third contact hole CNT3 penetrating the via insulting layer VIA1. Through this, a signal flowing through the first connection electrode CE1 may be transmitted to the source electrode SE. The second connection electrode CE2 may be connected to the second drain electrode DE2 through a fourth contact hole CNT4 penetrating the via insulting layer VIA1. Through this, a signal flowing through the first connection electrode CE1 may be transmitted to the second connection electrode CE2 through the source electrode SE, the active layer ACT, and the second drain electrode DE2.

In embodiments, a thickness of the second connection electrode CE2 in the second direction DR2 may be thicker than a thickness of the first connection electrode CE1 in the second direction DR2.

The second via insulating layer VIA2 may be disposed on the first via insulating layer VIA1 to cover the first connection electrode CE1. In embodiments, the second via insulating layer VIA2 may be formed of an organic insulating material such as polyimide (“PI”).

The second via insulating layer VIA2 may include an opening exposing the second connection electrode CE2. That is, the second connection electrode CE2 may fill the opening of the second via insulating layer VIA2. The second connection electrode CE2 may pass through the second via insulating layer VIA2 and contact the bottom surface of the first pixel electrode PE1. Through this, the second connection electrode CE2 may be connected to the first pixel electrode PE1. A height of the second via insulating layer VIA2 in the second direction DR2 may be substantially the same as a height of the second connection electrode CE2 in the second direction DR2.

In embodiments, the shortest distance D2 between the first connection electrode CE1 and the first pixel electrode PE1 may be 3000 angstroms or more. That is, the shortest distance D2 between an upper surface of the second via insulating layer VIA2 and an upper surface of the first connection electrode CE1 may be at least 3000 angstroms or more. Through this, it is possible to prevent generation of a parasitic capacitor between the first connection electrode CE1 and the first pixel electrode PE1.

The first pixel electrode PE1 may be disposed on the second via insulating layer VIA2. The first pixel electrode PE1 may contact the second connection electrode CE2. Since a height of the second connection electrode CE2 in the second direction DR2 and a height of the second via insulating layer VIA2 in the second direction DR2 are substantially the same, a lower surface of the first pixel electrode PE1 may directly contact an upper surface of the second connection electrode CE2. The first pixel electrode PE1 may include a metal, an alloy, a conductive metal oxide, a transparent conductive material, or the like. The first pixel electrode PE1 may receive a signal through the second connection electrode CE2. In embodiments, the first pixel electrode PE1 may be an anode electrode.

In this way, if a thickness of the second connection electrode CE2 in the second direction DR2 is formed to be thick enough, then the second connection electrode CE2 and the first pixel electrode PE1 may directly contact each other without a contact hole. Through this, it is possible to improve the flatness of the second via insulating layer VIA2 even after the process of forming the contact hole, which may affect the flatness of the second via insulating layer VIA2. As a result, the organic light emitting diode (OLED) is disposed flat, so that the luminous efficiency of the display device may be improved.

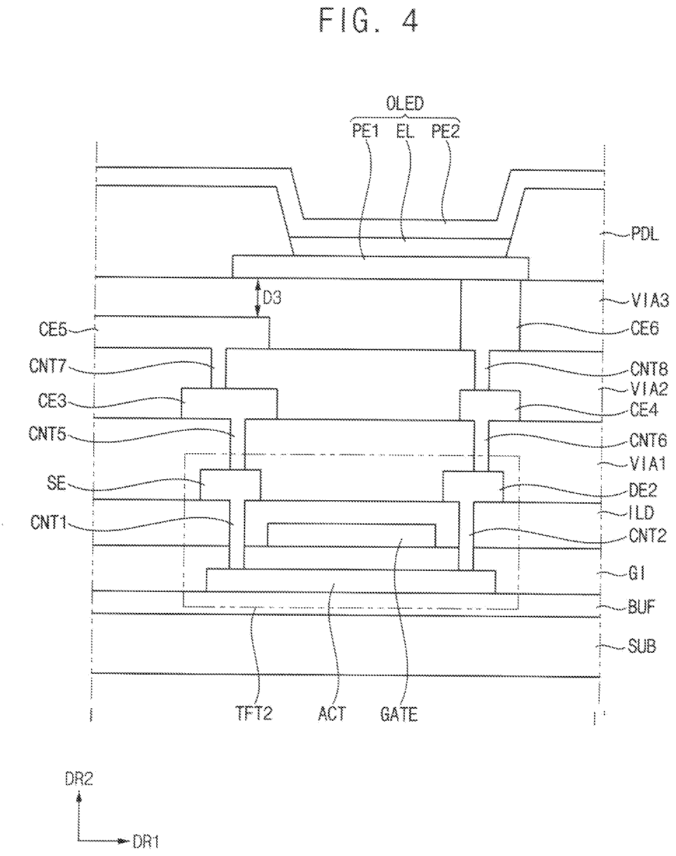

FIG. 4 is a cross-sectional view illustrating an embodiment taken along line I-I′ of FIG. 1. FIG. 4 may be substantially the same as that of FIG. 2 except for a structure between the interlayer insulating layer ILD and the first pixel electrode PE1. Accordingly, the overlapping configuration will be omitted.

Referring to FIG. 4, the display device may include the substrate SUB, the buffer layer BUF, the gate insulating layer GI, the interlayer insulating layer ILD, the first via insulating layer VIA1, a third connection electrode CE3, a fourth connection electrode CE4, a fifth connection electrode CE5, a sixth connection electrode CE6, the second via insulating layer VIA2, a third via insulating layer VIA3, and the pixel defining layer PDL, the organic light emitting diode OLED, and the second transistor TFT2.

The source electrode SE and the second drain electrode DE2 may be disposed on the interlayer insulating layer ILD. The second drain electrode DE2 may be disposed to be spaced apart from the source electrode SE in the first direction DR1. The second drain electrode DE2 and the source electrode SE may have substantially the same thickness.

The first via insulating layer VIA1 may be disposed on the interlayer insulating layer ILD to cover the source electrode SE and the second drain electrode DE2. In embodiments, the first via insulating layer VIA1 may be formed of an organic insulating material such as polyimide (“PI”).

The third connection electrode CE3 and the fourth connection electrode CE4 may be disposed on the first via insulating layer VIA1. The fourth connection electrode CE4 may be disposed to be spaced apart from the third connection electrode CE3 in the first direction DR1. The third connection electrode CE3 and the fourth connection electrode CE4 may have substantially the same thickness. In embodiments, the third connection electrode CE3 may be connected to the source electrode SE through a fifth contact hole CNT5 penetrating the first via layer VIA1. The fourth connection electrode CE4 may be connected to the second drain electrode DE2 through a sixth contact hole CNT6 penetrating the first via layer VIA1.

The second via insulating layer VIA2 may be disposed on the first via insulating layer VIA1 to cover the third and fourth connection electrodes CE3, CE4. In embodiments, the second via insulating layer VIA2 may be formed of an organic insulating material such as polyimide (“PI”).

The fifth connection electrode CE5 and the sixth connection electrode CE6 may be disposed on the second via insulating layer VIA2. The fifth connection electrode CE5 and the sixth connection electrode CE6 may include a metal, an alloy, a conductive metal oxide, a transparent conductive material, and the like.

The fifth connection electrode CE5 may be connected to the third connection electrode CE3 through a seventh contact hole CNT7 penetrating the second via layer VIA2.

Through this, a signal flowing through the fifth connection electrode CE5 may be transmitted to the third connection electrode CE3 and the source electrode SE. The sixth connection electrode CE6 may be connected to the fourth connection electrode CE4 through an eighth contact hole CNT8 penetrating the second via layer VIA2. Through this, a signal flowing through the fifth connection electrode CE5 may be transmitted to the sixth connection electrode CE6 through the third connection electrode CE3, the source electrode SE, the active layer ACT, the second drain electrode DE2, and the fourth connection electrode CE4.

In embodiments, a thickness of the sixth connection electrode CE6 in the second direction DR2 may be thicker than a thickness of the fifth connection electrode CE5 in the second direction DR2.

The third via insulating layer VIA3 may cover the fifth connection electrode CE5 and may be disposed on the second via insulating layer VIA2. In embodiments, the third via insulating layer VIA3 may be formed of an organic insulating material such as polyimide (“OI”).

The third via insulating layer VIA3 may include an opening exposing the sixth connection electrode CE6. That is, the sixth connection electrode CE6 may fill the opening of the third via insulating layer VIA3. The sixth connection electrode CE6 may penetrate the third via insulating layer VIA3 and contact the first pixel electrode PE1. Through this, the sixth connection electrode CE6 may be connected to the first pixel electrode PE1. A height of the third via insulating layer VIA3 in the second direction DR2 may be substantially the same as a height of the sixth connection electrode CE6 in the second direction DR2.

In embodiments, a shortest distance D3 between the fifth connection electrode CE5 and the first pixel electrode PE1 may be 3000 angstroms or more. That is, a shortest distance D3 between an upper surface of the third via insulating layer VIA3 and an upper surface of the fifth connection electrode CE5 may be at least 3000 angstroms. Through this, it is possible to prevent generation of a parasitic capacitor between the fifth connection electrode CE5 and the first pixel electrode PE1.

The first pixel electrode PE1 may be disposed on the third via insulating layer VIA3. The first pixel electrode PE1 may contact the sixth connection electrode CE6. Since a height of the sixth connection electrode CE6 in the second direction DR2 and a height of the third via insulating layer VIA3 in the second direction DR2 are substantially the same, a lower surface of the first pixel electrode PE1 may directly contact an upper surface of the sixth connection electrode CE6. The first pixel electrode PE1 may include a metal, an alloy, a conductive metal oxide, a transparent conductive material, or the like. The first pixel electrode PE1 may receive a signal through the sixth connection electrode CE6. In embodiments, the first pixel electrode PE1 may be an anode electrode.

In this way, if a thickness of the sixth connection electrode CE6 in the second direction DR2 is formed to be thick enough, then the sixth connection electrode CE6 and the first pixel electrode PE1 may directly contact each other without a contact hole. Through this, it is possible to improve the flatness of the third via insulating layer VIA3 even after the process of forming the contact hole, which may affect flatness of the third via insulating layer VIA3. As a result, the organic light emitting diode (OLED) is disposed flat, so that the luminous efficiency of the display device may be improved.

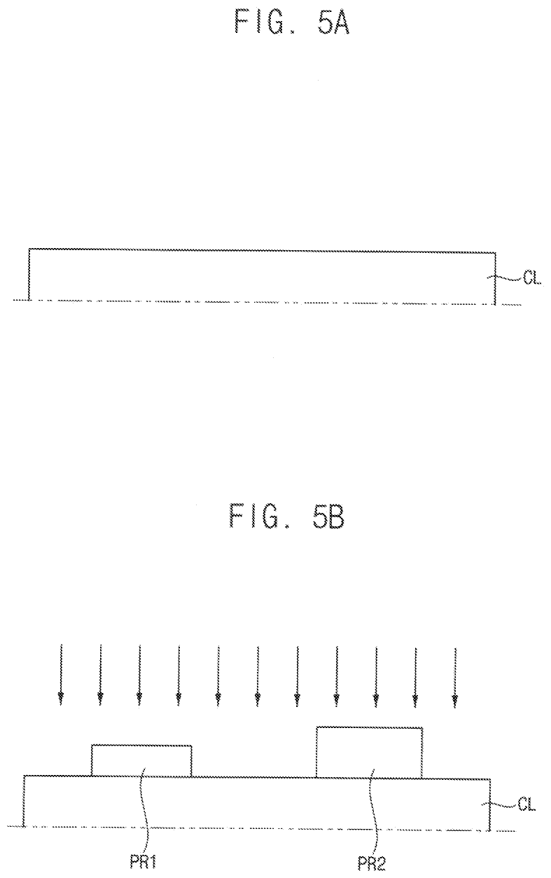

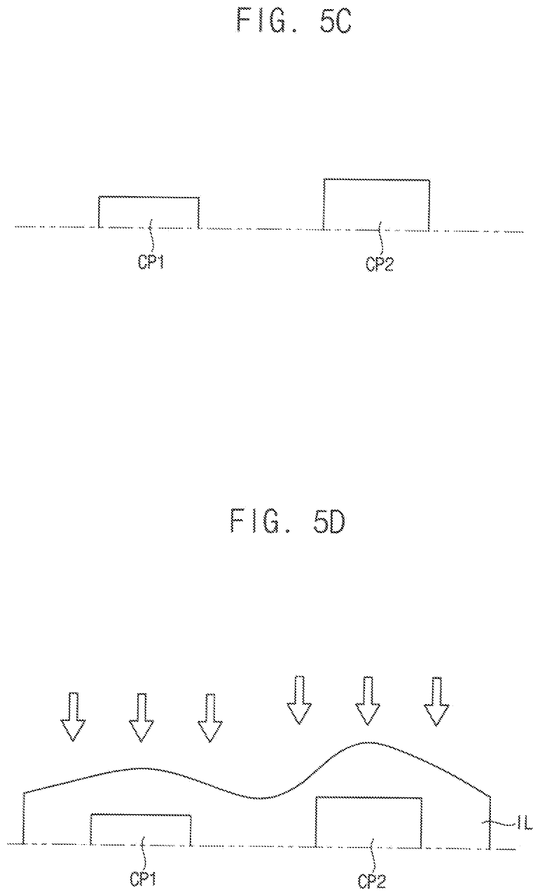

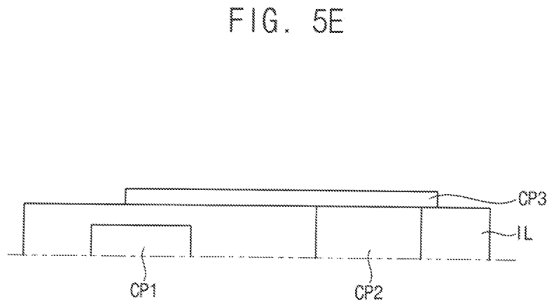

FIGS. 5A, 5B, 5C, 5D, and 5E are diagrams illustrating a process of manufacturing the flexible display device of FIG. 1.

Referring to FIG. 5A, at first, a conductive layer CL may be provided. The conductive layer CL may be disposed on the insulating layer. For example, the conductive layer CL may be disposed on the interlayer insulating layer ILD of FIG. 2. Alternatively, the conductive layer CL may be disposed on the first via insulating layer VIA1 of FIG. 2 or the second via insulating layer VIA2 of FIG. 2. In embodiments, the conductive layer CL may include a metal, an alloy, a conductive metal oxide, a transparent conductive material, and the like.

Referring to FIG. 5B, a first photoresist pattern PR1 and a second photoresist pattern PR2 may be disposed on the conductive layer CL. The second photoresist pattern PR2 may be thicker than the first photoresist pattern PR1. Accordingly, the conductive layer CL may be etched using the first and second photoresist patterns PR1, PR2 as a mask. In embodiments, since the first and second photoresist patterns PR1, PR2 have different thicknesses, the conductive layer CL may have different degrees of etching for each part.

Alternatively, in embodiments, the conductive layer CL may be exposed to different parts by using a mask and a halftone mask, followed by etching. In this case, the degree of etching of the conductive layer CL may be different for each part.

Referring to FIG. 5C, a first conductive pattern CP1 and a second conductive pattern CP2 may be formed by etching. The thickness of the second conductive pattern CP2 may be thicker than the thickness of the first conductive pattern CP1.

In embodiments, the first conductive pattern CP1 may correspond to the source electrode SE of FIG. 2, and the second conductive pattern CP2 may correspond to the first drain electrode DE1 of FIG. 2. Alternatively, in embodiments, the first conductive pattern CP1 may correspond to the first connection electrode CE1 of FIG. 3, and the second conductive pattern CP2 may correspond the second connection electrode CE2 of FIG. 3. Alternatively, in embodiments, the first conductive pattern CP1 may correspond to the fifth connection electrode CE5 of FIG. 4, and the second conductive pattern CP2 may correspond to the sixth connection electrode CE6 of FIG. 4.

Referring to FIG. 5D, an insulating layer IL may be disposed on the first and second conductive patterns CP1 and CP2. In embodiments, the insulating layer IL may correspond to the interlayer insulating layer IL of FIG. 2. Alternatively, in embodiments, the insulating layer IL may correspond to the first via insulating layer VIA1 of FIG. 3. Alternatively, in embodiments, the insulating layer IL may correspond to the second via insulating layer VIA2 of FIG. 4.

The insulating layer IL may not have a flat upper surface. Accordingly, a planarization process may be performed on the upper surface of the insulating layer IL. For example, the upper surface of the insulating layer IL may be planarized by a chemical-mechanical polishing (“CMP”) process. In this case, the planarization process may be performed so that the second conductive pattern CP2 may be exposed to the outside. In this case, a conductive pattern (i.e., the first pixel electrode PE1 in FIG. 2) or the like disposed on the second conductive pattern CP2 may be connected to the second conductive pattern CP2 without a contact hole. That is, the second conductive pattern CP2 and the conductive pattern may be directly connected without any contact hole.

Referring to FIG. 5E, a third conductive pattern CP3 may be disposed to contact the insulating layer IL and the second conductive pattern CP2. In this way, the third conductive pattern CP3 may be disposed in direct contact with the second conductive pattern CP2 without using a contact hole. For this reason, it is possible to prevent the third conductive pattern CP3 from not being flatly disposed due to a decrease in the flatness of the insulating layer IL in the process of forming the contact hole.

In embodiments, the third conductive pattern CP3 may correspond to the first pixel electrode PE1 of FIGS. 2, 3, and 4. In this case, since the organic light emitting diode OLED is disposed flat, the luminous efficiency of the display device may be improved.

The foregoing is illustrative of the present disclosure and is not to be construed as limiting thereof. Although a few example embodiments of the present disclosure have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of the present disclosure and is not to be construed as limited to the specific example embodiments disclosed, and that modifications to the disclosed example embodiments, as well as other example embodiments, are intended to be included within the scope of the appended claims. The present disclosure is defined by the following claims, with equivalents of the claims to be included therein.

What is claimed is:

1. A flexible display device comprising:
an active layer;
a source electrode disposed on the active layer, and connected to the active layer by a first contact hole;
a drain electrode disposed on a same layer as the source electrode and spaced apart from the source electrode in a first direction, and connected to the active layer by a second contact hole;
a first pixel electrode disposed on the drain electrode and including a lower surface electrically connected to the drain electrode while contacting an upper surface of the drain electrode; and
a via insulating layer disposed between the source electrode and the first pixel electrode, the via insulating layer covering an entirety of the source electrode,
wherein the drain electrode penetrates through the via insulating layer and is directly connected to the first pixel electrode.

2. The flexible display device of claim 1,
wherein the source electrode has a first thickness in a second direction perpendicular to the first direction, the drain electrode has a second thickness in the second direction, and the second thickness is thicker than the first thickness.

3. The flexible display device of claim 1,
wherein the via insulating layer exposes the upper surface of the drain electrode.

4. The flexible display device of claim 3,
wherein the upper surface of the drain electrode and an upper surface of the via insulating layer are disposed on a same line.

5. The flexible display device of claim 3,
wherein a shortest distance between an upper surface of the source electrode and an upper surface of the via insulating layer is 3000 angstroms.

6. The flexible display device of claim 1, further comprising:
a light emitting layer disposed on the first pixel electrode; and
a second pixel electrode disposed on the light emitting layer.

7. A flexible display device comprising:
an active layer;
a source electrode disposed on the active layer and connected to the active layer by a first contact hole;
a drain electrode disposed on the active layer and connected to the active layer by a second contact hole;
a first connection electrode disposed on the source electrode and connected to the source electrode by a third contact hole;
a second connection electrode disposed on a same layer as the first connection electrode and connected to the drain electrode by a fourth contact hole;
a first pixel electrode disposed on the second connection electrode and including a lower surface while contacting an upper surface of the second connection electrode; and
a via insulating layer disposed between the first connection electrode and the first pixel electrode, the via insulating layer covering an entirety of the first connection electrode,
wherein the second connection electrode penetrates through the via insulating layer and is directly connected to the first pixel electrode.

8. The flexible display device of claim 7,
wherein the first connection electrode has a first thickness in a second direction perpendicular to the first direction, the second connection electrode has a second thickness in the second direction, and the second thickness is thicker than the first thickness.

9. The flexible display device of claim 8,
wherein a thickness of the source electrode in the second direction is equal to a thickness of the drain electrode in the second direction.

10. The flexible display device of claim 7,
wherein the via insulating layer exposes the upper surface of the second connection electrode.

11. The flexible display device of claim 10,
wherein the upper surface of the second connection electrode and an upper surface of the via insulating layer are disposed on a same line.

12. The flexible display device of claim 10,
wherein a shortest distance between an upper surface of the first connection electrode and an upper surface of the via insulating layer is 3000 angstroms.

13. The flexible display device of claim 7, further comprising:
a light emitting layer disposed on the first pixel electrode; and
a second pixel electrode disposed on the light emitting layer.

14. A flexible display device comprising:
an active layer;
a source electrode disposed on the active layer and connected to the active layer by a first contact hole;
a drain electrode disposed on the active layer and connected to the active layer by a second electrode;
a first connection electrode disposed on the source electrode and connected to the source electrode by a third contact hole;
a second connection electrode disposed on the drain electrode and connected to the drain electrode by a fourth contact hole;
a third connection electrode disposed on the first connection electrode and connected to the first connection electrode by a fifth contact hole;
a fourth connection electrode disposed on a same layer as the third connection electrode and connected to the second connection electrode by a sixth contact hole;
a first pixel electrode disposed on the fourth connection electrode and including a lower surface while contacting an upper surface of the fourth connection electrode; and
a via insulating layer disposed between the third connection electrode and the first pixel electrode, the via insulating layer covering an entirety of the third connection electrode,
wherein the fourth connection electrode penetrates through the via insulating layer and is directly connected to the first pixel electrode.

15. The flexible display device of claim 14,
wherein the third connection electrode has a first thickness in a second direction perpendicular to the first direction, the fourth connection electrode has a second thickness in the second direction, and the second thickness is thicker than the first thickness.

16. The flexible display device of claim 15,
wherein a thickness of the source electrode in the second direction and a thickness of the drain electrode in the second direction are same, and a thickness of the first connection electrode in the second direction and a thickness of the second connection electrode in the second direction are same.

17. The flexible display device of claim 14,
wherein the via insulating layer exposes the upper surface of the fourth connection electrode.

18. The flexible display device of claim 17,
wherein the upper surface of the fourth connection electrode and an upper surface of the via insulating layer are disposed on a same line.

19. The flexible display device of claim 17,
wherein a shortest distance between an upper surface of the third connection electrode and an upper surface of the via insulating layer is 3000 angstroms.

20. The flexible display device of claim 14, further comprising:
a light emitting layer disposed on the first pixel electrode; and
a second pixel electrode disposed on the light emitting layer.
